(19) United States
(12) Patent Application Publication
(10) Pub. No.: US 2021/0050498 A1
(43) Pub. Date: Feb. 18, 2021

(54) MICRO LED ELEMENT AND MICRO LED DISPLAY MODULE HAVING THE SAME

(71) Applicant: SAMSUNG ELECTRONICS CO., LTD., Suwon-si (KR)

(72) Inventors: Yoonsuk LEE, Suwon-si (KR); Eunhye KIM, Suwon-si (KR); Dongyeob LEE, Suwon-si (KR); Sangmoo PARK, Suwon-si (KR)

(73) Assignee: SAMSUNG ELECTRONICS CO., LTD., Suwon-si (KR)

(21) Appl. No.: 16/926,161

(22) Filed: Jul. 10, 2020

(30) Foreign Application Priority Data
Aug. 13, 2019 (KR) 10-2019-0098885

(51) Int. Cl. H01L 33/62; H01L 25/075; H01L 23/00

(52) U.S. Cl. CPC H01L 33/62; H01L 25/0753; H01L 24/29; H01L 24/83; H01L 2224/83851; H01L 2224/29811; H01L 2224/29839; H01L 2224/29844; H01L 2224/29847; H01L 2933/0066

(57) ABSTRACT

A light emitting diode (LED) element is provided. The LED element includes: an active layer configured to generate light; a first semiconductor layer disposed on a first surface of the active layer and doped with an n-type dopant; a second semiconductor layer disposed on a second surface of the active layer opposite to the first surface, the second semiconductor layer being doped with a p-type dopant; a first electrode pad and a second electrode pad electrically connected to the first semiconductor layer and the second semiconductor layer, respectively, the first electrode pad comprising a first contact surface and the second electrode pad comprising a second contact surface; and a conductive filler disposed on at least one contact surface from among the first contact surface and the second contact surface to increase a contact area of the at least one contact surface.

CROSS-REFERENCE TO RELATED APPLICATION(S)

This application is based on and claims priority under 35 U.S.C. §119 to Korean Patent Application No. 10-2019-0098885, filed on Aug. 13, 2019, in the Korean Intellectual Property Office, the disclosure of which is incorporated by reference herein in its entirety.

### BACKGROUND

### 1. Field

The disclosure relates to a light emitting diode (LED) element having improved electrical structure stability and an LED display module including the same.

### 2. Description of Related Art

An LED element is formed of an inorganic light emitting material and emits light on its own to display an image. In addition, a plurality of LED elements having a short side size of 100 μm or less may be disposed on a substrate to receive driving signals from the substrate, thereby implementing a display screen of high color, high brightness, and high resolution such as 4K or 8K. In order to receive electrical signals such as the driving signals and power from the substrate, the LED element needs a stable electrical connection with the substrate.

A micro-luminescent diode (e.g., micro LED, mLED, or μLED) display panel is a flat display panel that includes a plurality of inorganic LEDs that are each smaller than 100 micrometers.

A micro LED display panel provides improved contrast, faster response time, and higher energy efficiency as compared to those of a liquid crystal panel that requires a back light.

Although both organic LEDs (OLEDs) and micro LEDs have high energy efficiency, micro LEDs are brighter, have improved luminous efficiency, and have a longer lifespan as compared to OLEDs.

### SUMMARY

In accordance with an aspect of the disclosure, a light emitting diode (LED) element includes an active layer configured to generate light; a first semiconductor layer disposed on a first surface of the active layer and doped with an n-type dopant; a second semiconductor layer disposed on a second surface of the active layer opposite to the first surface, the second semiconductor layer being doped with a p-type dopant; a first electrode pad and a second electrode pad electrically connected to the first semiconductor layer and the second semiconductor layer, respectively, the first electrode pad including a first contact surface and the second electrode pad including a second contact surface; and a conductive filler disposed on at least one contact surface from among the first contact surface and the second contact surface to increase a contact area of the at least one contact surface.

A portion of the at least one contact surface is exposed through the conductive filler.

A surface of the conductive filler may be substantially coplanar with the at least one contact surface.

The conductive filler may cover an entirety of the at least one contact surface.

The first semiconductor layer may include a light exposure surface that transmits the light generated in the active layer, and the first electrode pad and the second electrode pad may be disposed on an opposite side of the first semiconductor layer with respect to the light exposure surface.

At least one contact surface from among the first contact surface and the second contact surface has a dent formed therein and the conductive filler disposed on the at least one contact surface to fill the dent.

In accordance with an aspect of the disclosure, a light emitting diode (LED) display module includes a substrate; a first connection pad and a second connection pad formed on a surface of the substrate; an LED element disposed on the substrate; and an adhesive layer disposed on the substrate to electrically connect the LED element to the substrate, wherein the LED element includes a first electrode pad and a second electrode pad disposed to face the first connection pad and the second connection pad, respectively, the first electrode pad including a first contact surface and the second electrode pad comprising a second contact surface; and a conductive filler configured to increase a contact area of at least one contact surface from among the first contact surface of the first electrode pad and the second contact surface of the second electrode pad.

A portion of the at least one contact surface is exposed through the conductive filler.

The conductive filler may cover an entirety of the at least one contact surface.

The adhesive layer may include a plurality of conductive particles, and the plurality of conductive particles may be disposed between the first electrode pad and the first connection pad to electrically connect the first electrode pad to the first connection pad, and may be disposed between the second electrode pad and the second connection pad to electrically connect the second electrode pad to the second connection pad.

The adhesive layer may include an anisotropic conductive film (ACF) or an anisotropic conductive paste (ACP).

In accordance with an aspect of the disclosure, a method of manufacturing a light emitting diode (LED) element includes checking a contact area of at least one contact surface from a first contact surface of a first electrode pad and a second contact surface of a second electrode pad of the LED element; determining whether a conductive filler of the LED element is formed, based on the checked contact area; and forming the conductive filler on the at least one contact surface based on a result of the determining of whether the conductive filler is formed.

The determining of whether the conductive filler is formed may be performed based on whether the checked contact area exceeds a predetermined area value.

The method may further include, after the forming of the conductive filler, inspecting a contact area of the conductive filler.

The forming of the conductive filler may include coating a base layer on the LED element to expose the at least one contact surface; coating a photoresist layer on the base layer; forming a plating hole on the at least one contact surface; depositing the conductive filler in the plating hole; and removing the base layer and the photoresist layer.

The forming of the conductive filler may include coating a first photoresist layer to cover the LED element; coating a seed layer on the first photoresist layer; coating a second photoresist layer on the seed layer; forming a plating hole on the at least one contact surface; depositing the conductive filler in the plating hole; and removing the first photoresist layer, the seed layer, and the second photoresist layer.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view illustrating a micro LED element according to an embodiment;

FIG. 2 is a top view illustrating the micro LED element according to an embodiment;

FIG. 3 is a cross-sectional view illustrating a portion of a micro LED display module according to an embodiment;

FIG. 4 is a cross-sectional view illustrating a micro LED element according to an embodiment;

FIG. 5 is a top view illustrating the micro LED element according to an embodiment;

FIG. 6 is a cross-sectional view illustrating a portion of a micro LED display module according to an embodiment;

FIG. 7 is a cross-sectional view illustrating a micro LED element in which a conductive filler is not formed;

FIG. 8 is a cross-sectional view illustrating that a base layer is formed in a structure of FIG. 7;

FIG. 9 is a cross-sectional view illustrating that a photoresist layer is formed in a structure of FIG. 8;

FIG. 10A is a cross-sectional view illustrating that plating holes are formed on a plurality of electrode pads according to an embodiment;

FIG. 10B is a cross-sectional view illustrating that a conductive filler is formed through a plating process in the plating holes formed according to an embodiment;

FIG. 11A is a cross-sectional view illustrating that a conductive filler is formed according to an embodiment;

FIG. 11B is a cross-sectional view illustrating that a conductive filler is formed according to an embodiment;

FIG. 11C is a flowchart illustrating a method of manufacturing a micro LED element according to an embodiment;

FIG. 12A is a cross-sectional view illustrating a process of forming a conductive filler according to an embodiment;

FIG. 12B is a cross-sectional view illustrating that the conductive filler is formed in plating holes formed in a structure of FIG. 12A;

FIG. 12C is a cross-sectional view illustrating that the conductive filler is formed according to the process according to an embodiment;

FIG. 13 is a cross-sectional view illustrating that an adhesive layer is coated on a substrate according to an embodiment;

FIG. 14A is a cross-sectional view illustrating that the micro LED element according to an embodiment is transferred in a structure of FIG. 13;

FIG. 14B is a cross-sectional view illustrating that the micro LED element according to an embodiment is coupled to the substrate;

FIG. 15A is a cross-sectional view illustrating that a micro LED element according to an embodiment is transferred in a structure of FIG. 13; and

FIG. 15B is a cross-sectional view illustrating that the micro LED element according to an embodiment is coupled to a substrate.

### DETAILED DESCRIPTION

In order to fully understand the configuration and effect of the disclosure, embodiments of the disclosure will be described with reference to the accompanying drawings. However, the disclosure is not limited to embodiments disclosed below, but may be implemented in various forms and may be variously modified. However, the description of the embodiments is provided only to make the disclosure complete, and to fully inform the scope of the disclosure to those skilled in the art. In the accompanying drawings, for convenience of description, the size of the components is illustrated to be larger than the actual size, and the ratio of each component may be exaggerated or reduced.

When one component is referred to as being “on” or “in contact with” another component, it is to be understood that it may be in direct contact with or connected on another component, but there may be another component therebetween. On the other hand, when one component is referred to as being “directly on” or “in direct contact with” another component, it is to be understood that there may not be another component therebetween. Other expressions describing a relationship between the components, that is, “between”, “directly between”, and the like should be similarly interpreted.

Terms such as first and second may be used to describe various components, but the components should not be limited by the terms. The terms may be used only for the purpose of distinguishing one component from another component. For example, without departing from the scope of the disclosure, a first component may be referred to as a second component, and similarly, the second component may also be referred to as the first component.

Singular expressions include plural expressions unless the context clearly indicates otherwise. The terms “comprises”, “including” or “having” are intended to indicate that there is a feature, number, step, operation, component, part, or combination thereof described on the specification, and that there may be one or more other features or numbers, and it may be interpreted that steps, operations, components, parts or combinations thereof may be added.

Unless otherwise defined, terms used in the embodiments of the disclosure may be interpreted as having meanings commonly known to those skilled in the art.

The disclosure may provide an LED element having improved electrical structure stability and a method of manufacturing an LED element.

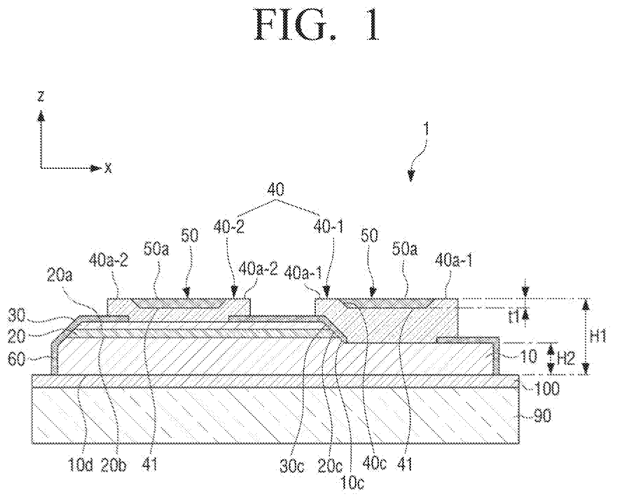

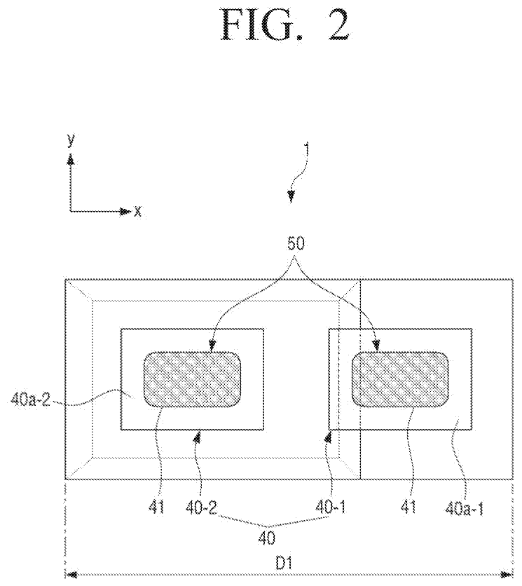

Hereinafter, a structure of a micro light emitting diode (LED) element 1 according to an embodiment of the disclosure will be described in detail with reference to FIGS. 1 and 2.

FIG. 1 is a cross-sectional view illustrating a micro LED element 1 according to an embodiment of the disclosure and FIG. 2 is a top view illustrating the micro LED element 1 according to an embodiment.

As illustrated in FIGS. 1 and 2, a micro LED element 1 may include an active layer 20 for generating light, a first semiconductor layer 10 disposed on a first surface 20b of the active layer 20 and doped with an n-type dopant, and a second semiconductor layer 30 disposed on a second surface 20a of the active layer 20 opposite to the first surface 20b and doped with a p-type dopant.

That is, the active layer 20 and the second semiconductor layer 30 may be sequentially stacked on the first semiconductor layer 10.

The first semiconductor layer 10 is a semiconductor layer formed by being grown on a growth substrate 90, and may have an n-type conductive type. Specifically, the first semiconductor layer 10 may be formed of a layer doped with an n-type dopant. For example, the first semiconductor layer 10 may have n-type conductivity by doping n-type dopants such as Si, Ge, Sn, Se, and Te.

In addition, the first semiconductor layer 10 determines a size of the micro LED element 1, and a size of the first semiconductor layer 10 may be regarded as the size of the micro LED element 1. That is, an area of the first semiconductor layer 10 on an x-y plane as shown in FIG. 1 may correspond to an area of the micro LED element 1.

A length D1 as shown in FIG. 2 of the first semiconductor layer 10 may be 250 μm or less. That is, a length of the micro LED element 1 may be 250 μm or less. Further, a first height H1 of the micro LED element 1 may be 7 μm or less. Here, the first height H1 may mean a length from a light exposure surface 10d of the first semiconductor layer 10 to contact surfaces 40a-1 and 40a-2 of a plurality of electrode pads 40.

Further, the first semiconductor layer 10 may have a rectangular shape in a cross section parallel to the x-y plane, but is not limited thereto and may, for example, have a square shape.

Further, the active layer 20 may be formed on a portion of an area of an upper surface of the first semiconductor layer 10. That is, the active layer 20 and the second semiconductor layer 30 stacked on the active layer 20 may be formed only on the portion, not on an entire area of the upper surface of the first semiconductor layer 10.

Accordingly, the first electrode pad 40-1 is disposed on at least a portion of the remaining area of the upper surface of the first semiconductor layer 10 where the active layer 20 is not formed, so that the first semiconductor layer 10 and the first electrode pad 40-1 may be electrically and physically connected.

Further, a first inclined surface 10c may be formed at an edge area of the portion of the first semiconductor layer 10 that is in contact with the first surface 20b of the active layer 20. Here, the first inclined surface 10c may be formed by an etching process of a manufacturing process of the micro LED element 1. Here, the first inclined surface 10c may be formed at a predetermined angle with respect to the x-y plane of the first semiconductor layer 10.

Further, the first semiconductor layer 10 may be formed of a material through which light may pass. Accordingly, the light generated from the active layer 20 may pass through the first semiconductor layer 10 and may be irradiated to the light exposure surface 10d of the first semiconductor layer 10.

Here, the light exposure surface 10d may mean one surface of the micro LED element 1 through which the light generated from the active layer 20 is exposed (i.e., transmitted).

Therefore, because the first semiconductor layer 10 is formed of a material having high light transmittance, light loss is reduced even though the light generated from the active layer 20 passes through the first semiconductor layer 10, thereby improving a light efficiency of the micro LED element 1.

The second semiconductor layer 30 may have a p-type conductive type. Specifically, the second semiconductor layer 30 may be formed of a layer doped with a p-type dopant. For example, the second semiconductor layer 30 may have p-type conductivity by doping p-type dopants such as Zn, Mg, Co, Ni, Cu, Fe, and C.

The second semiconductor layer 30 may be disposed on the second surface 20a of the active layer 20. Further, a cross-sectional area of the second semiconductor layer 30 parallel to the x-y plane may be smaller than a cross-sectional area of the active layer 20 parallel to the x-y plane.

That is, the second semiconductor layer 30 may have a smaller cross-sectional area toward an upper direction with respect to the active layer 20. Here, the upper direction may mean a direction opposite to a direction in which the first semiconductor layer 10 is disposed relative to the second semiconductor layer 30. In other words, the upper direction may be the Z direction shown in FIG. 1 from the first semiconductor layer 10 to the second semiconductor layer 30. For example, as the second semiconductor layer 30 moves away from the first semiconductor layer 10 in the upper direction, the cross-sectional area thereof may gradually decrease.

Further, the second semiconductor layer 30 may have a rectangular shape in a cross section parallel to the x-y plane, but is not limited thereto and may have, for example, a square shape.

The second semiconductor layer 30 may be formed of the same base material as that of the first semiconductor layer 10, but may have a conductive type complementary to that of the first semiconductor layer 10 because the dopant is different.

For example, the first semiconductor layer 10 may provide electrons, and the second semiconductor layer 30 may provide holes.

Further, the second semiconductor layer 30 may include a second inclined surface 30c, and the second inclined surface 30c may be formed at the same angle with respect to the first inclined surface 10c of the first semiconductor layer 10, a third inclined surface 20c of the active layer 20, and the x-y plane of the first semiconductor layer 10 as shown in FIG. 1.

Here, the second inclined surface 30c may be formed by an etching process in the manufacturing process of the micro LED element 1.

The active layer 20 may be disposed between the first semiconductor layer 10 and the second semiconductor layer 30 to generate light. That is, the second semiconductor layer 30, the active layer 20, and the first semiconductor layer 10 may be sequentially stacked.

The active layer 20 is a layer that outputs light of a predetermined wavelength while the electrons provided from the first semiconductor layer 10 and the holes provided from the second semiconductor layer 30 are recombined, and may have a single quantum well structure or a multi-quantum well (MQW) structure by alternately stacking well layers and barrier layers.

Accordingly, the light generated in the active layer 20 may be irradiated to upper and lower surfaces and side surfaces of the active layer 20.

In addition, the active layer 20 may have a third inclined surface 20c that is inclined to be wider in a lower area in the Z-axis direction. Here, the lower area may mean a direction in which the first semiconductor layer 10 is disposed relative to the active layer 20.

That is, the cross-sectional area of the active layer 20 may gradually decrease with increasing distance from the first semiconductor layer 10.

In addition, the cross-sectional area of the active layer 20 parallel to the x-y plane may be smaller than a cross-sectional area of the first semiconductor layer 10 and larger than the cross-sectional area of the second semiconductor layer 30.

Further, the micro LED element 1 may include a first electrode pad 40-1 connected to the first semiconductor layer 10 and a second electrode pad 40-2 electrically connected to the second semiconductor layer 30. The first electrode pad 40-1 and the second electrode pad 40-2 may each have a dent 41 disposed on the respective contact surfaces 40a-1 and 40a-2 and a conductive filler 50 provided to fill the dent 41 of each of the first electrode pad 40-1 and the second electrode pad 40-2.

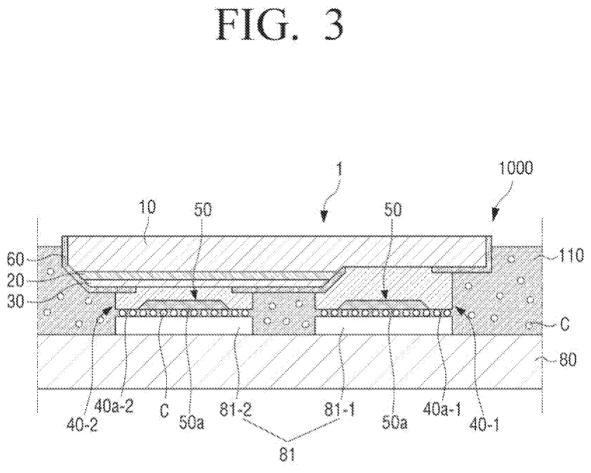

The first electrode pad 40-1 may be disposed on the first semiconductor layer 10 to be in direct contact with the first semiconductor layer 10. Accordingly, the first electrode pad 40-1 may transmit current and electrical signals transmitted from a first connection pad 81-1 (see FIG. 3) of a substrate 80 to the first semiconductor layer 10.

Further, the first electrode pad 40-1 may be entirely in contact with the first semiconductor layer 10, but may be in contact with only a portion of the first semiconductor layer 10. For example, as illustrated in FIG. 1, an insulating member 60 is disposed to partially surround the first semiconductor layer 10, and the first electrode pad 40-1 may be electrically and physically connected to the first semiconductor layer 10 through a space in which the insulating member 60 is not formed.

Further, the first electrode pad 40-1 and the second electrode pad 40-2 may be disposed in a direction opposite to the light exposure surface 10d with respect to the first semiconductor layer 10. For example, the micro LED element 1 may be a flip chip.

Accordingly, because the first electrode pad 40-1 and the second electrode pad 40-2 disposed in the direction opposite to the light exposure surface 10d do not block the light of the micro LED element 1 irradiated to the light exposure surface 10d, the light efficiency of the micro LED element 1 may be increased.

Further, the first electrode pad 40-1 and the second electrode pad 40-2 may be disposed at predetermined intervals. Here, the predetermined interval may mean an interval in which the first electrode pad 40-1 and the second electrode pad 40-2 may not be directly and electrically connected to each other.

In addition, heights of the first electrode pad 40-1 and the second electrode pad 40-2 with respect to the first semiconductor layer 10 may be the same as each other.

Accordingly, when the micro LED element 1 is disposed on the substrate 80, the micro LED element 1 is not disposed to be tilted in one direction, but may be disposed almost in parallel with a surface of the substrate 80 as shown in FIG. 3.

Therefore, it is possible to prevent the light emitted from the micro LED element 1 from being deflected and irradiated in one direction.

The first electrode pad 40-1 may be formed of a conductive material. For example, the first electrode pad 40-1 may be formed of a material having high electrical conductivity. For example, the first electrode pad 40-1 may be formed of Au, Ag, Cu, indium tin oxide (ITO), or the like.

Further, the first electrode pad 40-1 may be formed to partially cover edge areas of the active layer 20 and the second semiconductor layer 30. However, because the insulating member 60 is disposed between the first electrode pad 40-1 and the active layer 20 and the second semiconductor layer 30, the first electrode pad 40-1 is not electrically connected to the active layer 20 and the second semiconductor layer 30.

For example, the first electrode pad 40-1 may be disposed on and cover upper portions of the first inclined surface 10c of the first semiconductor layer 10, the second inclined surface 30c of the second semiconductor layer 30, and the third inclined surface 20c of the active layer 20.

Accordingly, light irradiated in the direction of the first electrode pad 40-1 of the light generated in the active layer 20 may be reflected by the first electrode pad 40-1 and irradiated to the light exposure surface 10d. Accordingly, the light efficiency of the micro LED element 1 may be improved.

A second height H2 from the light exposure surface 10d of the first semiconductor layer 10 to an opposite surface of the semiconductor layer 10 that is in contact with the first electrode pad 40-1 may be 2.24 μm or less.

Further, the first electrode pad 40-1 may include the first contact surface 40a-1 that contacts a first connection pad 81-1 of the substrate 80 and a dent 41 may be formed on the first contact surface 40a-1.

In addition, as illustrated in FIG. 2, the first electrode pad 40-1 may have a rectangular-shaped plane parallel to the x-y plane. However, the first electrode pad 40-1 may have, for example, a square-shaped plane parallel to the x-y plane.

The first contact surface 40a-1 may form one surface of the first electrode pad 40-1, and may be directly and electrically in contact with conductive particles C of an adhesive layer 110 (see FIG. 3).

The first contact surface 40a-1 may be formed parallel to the x-y plane. That is, the first contact surface 40a-1 may be formed to be flat in an area around the dent 41. Accordingly, when a conductive filler 50 is filled in the dent 41, an outer surface 50a (i.e., an upper surface in the Z direction as shown in FIG. 1) of the conductive filler 50 may be formed in parallel with and coplanar to the first contact surface 40a-1.

Therefore, when the micro LED element 1 is fixed on the substrate 80, the micro LED element 1 may be disposed so as not to be tilted in one direction, thereby uniformly irradiating the light.

The dent 41 is formed in the manufacturing process of the micro LED element 1 and may be formed on one surface of each of the first electrode pad 40-1 and the second electrode pad 40-2.

That is, the dent 41 is generated by partially damaging the surface of the first electrode pad 40-1 or the second electrode pad 40-2, and the dent 41 in the disclosure may include a case in which an edge of the pad is also damaged, in addition to a case in which only the center portion of the pad is damaged. That is, some or all of the central portions and edges on the first electrode pad 40-1 and the second electrode pad 40-2 may be included in the dents 41.

For example, the dent 41 formed on the first electrode pad 40-1 may have a shape corresponding to the shapes of the first inclined surface 10c of the first semiconductor layer 10, the second inclined surface 30c of the second semiconductor layer 30, and the third inclined surface 20c of the active layer 20, as the first electrode pad 40-1 is formed on the upper portions of the first inclined surface 10c of the first semiconductor layer 10, the second inclined surface 30c of the second semiconductor layer 30, and the third inclined surface 20c of the active layer 20.

Specifically, the dent 41 may include an inclined surface 40c formed around the dent 41, and the inclined surface 40c of the dent 41 may be disposed on (e.g., positioned above in the Z direction) the upper portions of the first inclined surface 10c of the first semiconductor layer 10, the second inclined surface 30c of the second semiconductor layer 30, and the third inclined surface 20c of the active layer 20.

That is, an angle formed by the inclined surface 40c of the dent 41 with respect to the light exposure surface 10d of the first semiconductor layer 10 may be the same as an angle formed by the first inclined surface 10c of the first semiconductor layer 10, the second inclined surface 30c of the second semiconductor layer 30, and the third inclined surface 20c of the active layer 20 with respect to the light exposure surface 10d of the first semiconductor layer 10.

The dent 41 may be formed on a mesa area by stacking the first electrode pad 40-1, which is a conductive material, on the mesa area of the micro LED element 1 formed by a mesa etching process.

Here, the mesa etching may mean that etching is performed only on a certain portion in order to form a predetermined area of the micro LED element 1 in a trapezoidal shape.

For example, edge areas of the first semiconductor layer 10, the second semiconductor layer 30, and the active layer 20 including the first inclined surface 10c of the first semiconductor layer 10, the second inclined surface 30c of the second semiconductor layer 30, and the third inclined surface 20c of the active layer 20 with respect to the light exposure surface 10d of the first semiconductor layer 10 may correspond to the mesa area.

A shape of the dent 41 may vary depending on a shape of the mesa area disposed under the dent 41. Further, a depth of the dent 41 may be smaller than the height of the electrode pad. Here, the height of the electrode pad may be about 5 μm.

The second electrode pad 40-2 may be disposed on the second semiconductor layer 30 to be in direct contact with the second semiconductor layer 30. Accordingly, the second electrode pad 40-2 may transmit current and electrical signals transmitted from a second connection pad 81-2 (see FIG. 3) of the substrate 80 to the second semiconductor layer 30.

Further, the second electrode pad 40-2 may be entirely in contact with the second semiconductor layer 30, but may be in contact with only a portion of the second semiconductor layer 30. For example, an insulating member 60 is disposed to partially surround the first semiconductor layer 10, and as illustrated in FIG. 1, the second electrode pad 40-2 may be electrically and physically connected to the second semiconductor layer 30 through a space in which the insulating member 60 is not formed.

The second electrode pad 40-2 may be formed of a conductive material, and may be formed of the same material as that of the first electrode pad 40-1 described above.

Further, the second electrode pad 40-2 may include a second contact surface 40a-2 that contacts a second connection pad 81-2 of the substrate 80 and the dent 41 formed on the second contact surface 40a-2.

In addition, as illustrated in FIG. 2, the second electrode pad 40-2 may have a rectangular-shaped plane parallel to the x-y plane. However, the second electrode pad 40-2 may have a square-shaped plane parallel to the x-y plane.

The second contact surface 40a-2 may form one surface of the second electrode pad 40-2, and may be directly and electrically in contact with conductive particles C of an adhesive layer 110 as shown in FIG. 3.

The second contact surface 40a-2 may be formed parallel to the x-y plane. That is, the second contact surface 40a-2 may be formed to be flat in an area around the dent 41. Accordingly, when the conductive filler 50 is filled in the dent 41, an outer surface 50a (i.e., an upper surface) of the conductive filler 50 may be substantially parallel to and coplanar with the second contact surface 40a-2.

Therefore, when the micro LED element 1 is fixed on the substrate 80, the micro LED element 1 may be disposed so as not to be tilted in one direction, thereby uniformly irradiating the light.

Further, the dent 41 formed on the second contact surface 40a-2 may be formed by a shape of a structure formed under the second electrode pad 40-2. For example, the dent 41 of the second contact surface 40a-2 may be formed due to a step formed by the insulating member 60.

Specifically, an inclined surface of the dent 41 of the second contact surface 40a-2 may be caused by a step between the second semiconductor layer 30 and the insulating member 60.

However, the first contact surface 40a-1 and the second contact surface 40a-2 are stacked structures of the micro LED element 1, and are generated in the same way by the mesa area generated by the etching process. Further, the first contact surface 40a-1 and the second contact surface 40a-2 may be formed in the manufacturing process of the micro LED element 1 without being limited to the etching process.

The conductive filler 50 may be disposed in the dents 41 formed in a plurality of electrode pads 40 to fill the dents 41. For example, the dent 41 of the first electrode pad 40-1 and the dent 41 of the second electrode pad 40-2 may be filled with the conductive filler 50.

That is, the conductive filler 50 may have a shape corresponding to the shape of the dent 41.

Further, the conductive filler 50 may be disposed on the contact surface of at least one of the first electrode pad 40-1 and the second electrode pad 40-2 to increase a contact area of at least one contact surface from the first contact surface 40a-1 and the second contact surface 40a-2.

Here, when the first electrode pad 40-1 and the second electrode pad 40-2 are electrically connected to the substrate 80 through the adhesive layer 110, the contact area may mean an area in which electrical contact is substantially implemented among the first electrode pad 40-1 and the second electrode pad 40-2.

For example, when the dents 41 are disposed on the first electrode pad 40-1 and the second electrode pad 40-2, the contact area may mean an area in which the dents 41 are excluded. That is, the contact area may mean an area of the contact surfaces 40a-1 and 40a-2 adjacent to the dents 41. In other words, the presence of the dents 41 causes portions of the upper surfaces of the first electrode pad 40-1 and the second electrode pad 40-2 not to be in contact with the adhesive layer 110. The conductive filler 50 is provided to increase the contact area between the first and second electrode pads 40-1 and 40-2 and the adhesive layer 110.

The conductive filler 50 is formed of a conductive material, and may be formed of a material having good electrical conductivity. For example, the conductive filler 50 is formed of a material such as Au, Ag, Sn, or Cu.

Further, the conductive filler 50 may be formed of the same material as that of the plurality of electrode pads 40, but is not limited thereto, and may be formed of a material different from that of the plurality of electrode pads 40.

In addition, a first thickness t1 of the conductive filler 50 may be the same as the depth of the dent 41. For example, the first thickness t1 of the conductive filler 50 may be 1.5 μm or less.

The conductive filler 50 may be disposed to expose a portion of the at least one contact surface 40a-1 or 40a-2. For example, the conductive filler 50 may be disposed to expose a portion of the contact surfaces 40a-1 and 40a-2 of the first electrode pad 40-1 and the second electrode pad 40-2.

For example, the outer surface 50a of the conductive filler 50 may be disposed to be substantially parallel to and coplanar with the contact surfaces 40a-1 and 40a-2 around the outer surface 50a of the conductive filler 50.

Accordingly, the conductive filler 50 may perform the same electrical function of the contact surfaces 40a-1 and 40a-2 of the plurality of electrode pads 40. That is, the conductive filler 50 may electrically connect the plurality of electrode pads 40 and the plurality of connection pads 81.

Therefore, the plurality of electrode pads 40 provided with the conductive filler 50 may substantially increase the contact area of the contact surfaces 40a-1 and 40a-2, thereby improving stability of the electrical connection of the micro LED element 1.

The insulating member 60 is formed of an insulating material, and may partially surround the first semiconductor layer 10, the second semiconductor layer 30, and the active layer 20. For example, the insulating member 60 may cover the first semiconductor layer 10, the second semiconductor layer 30, and the active layer 20, except for the light exposure surface 10d and for exposed areas that contact the first and second electrode pads 40-1 and 40-2.

Specifically, the insulating member 60 may cover a portion of the side surfaces and upper surface of the first semiconductor layer 10 except for the light exposure surface 10d. At this time, the insulating member 60 may not be formed in an area for direct contact between the first electrode pad 40-1 and the first semiconductor layer 10.

Further, the insulating member 60 may cover a portion of the side surfaces and upper surface of the second semiconductor layer 30. At this time, the insulating member 60 may not be formed in an area for direct contact between the second electrode pad 40-2 and the second semiconductor layer 30.

In addition, the insulating member 60 may cover the side surfaces of the active layer 20.

Accordingly, because the micro LED element 1 is electrically connected only through the plurality of electrode pads 40, the electrical stability of the micro LED element 1 may be improved. Further, the insulating member 60 may prevent leakage of the current and electrical signals from the micro LED element 1, thereby preventing influence of noise or the like on micro LED elements disposed adjacent to the micro LED element 1.

That is, the insulating member 60 may electrically shield the micro LED element 1.

A growth substrate 90 is a mother substrate for growing the first semiconductor layer 10, and may be formed of sapphire (Al₂O₃), silicon carbide (SiC), gallium nitride (GaN), indium gallium nitride (InGaN), aluminum gallium nitride (AlGaN), aluminum nitride (AlN), gallium oxide (Ga₂O₃), gallium arsenic (GaAs), or a silicon substrate.

Further, a buffer layer 100 may be formed between the growth substrate 90 and the first semiconductor layer 10. When a completed micro LED element 1 is separated from the growth substrate 90, the buffer layer 100 enables selective etching of the portion where the micro LED element 1 is positioned, and may reduce the degree of lattice mismatch between the growth substrate 90 and the micro LED element 1.

Hereinafter, a structure of a micro LED display module 1000 according to an embodiment will be described in detail with reference to FIG. 3.

FIG. 3 is a cross-sectional view illustrating a portion of a micro LED display module 1000 according to an embodiment.

A micro LED display module 1000 may include a substrate 80 having a first connection pad 81-1 and a second connection pad 81-2 formed on one surface thereof, a micro LED element 1 disposed on the substrate 80, and an adhesive layer 110 stacked on the substrate 80 to electrically connect the micro LED element 1 to the substrate 80.

The substrate 80 as shown in FIG. 3 is a unit constituting one micro LED display module 1000, and thousands to tens of thousands of micro LED elements 1 may be disposed on the substrate 80.

Further, the substrate 80 may fix at least one micro LED element 1 disposed on the substrate 80 and simultaneously operate the at least one micro LED element 1. For example, the substrate 80 may be formed of a thin film transistor layer or a printed circuit board (PCB) including a thin film transistor (TFT). That is, the substrate 80 may implement a high-color and high-luminance display image through the operation of at least one micro LED element 1.

Thin film transistor (TFT) that consists of the substrate 80 may not be limited to specific structures or types. Specifically, the thin film transistor may be formed by low-temperature polycrystalline silicon (LTPS) TFT, oxide TFT, Si TFT (polysilicon or a-silicon), organic TFT or graphene TFT, etc., and be applied by making only a P type (or N-type) MOSFET in the Si-wafer-CMOS process.

The substrate 80 may be referred to as a target substrate, a thin film transistor glass substrate, a printed circuit board (PCB), or a backplane.

A plurality of connection pads 81 are disposed at predetermined intervals on the substrate 80, and may be connected to one thin film transistor disposed in the substrate 80 to transmit electrical signals transmitted from the thin film transistor to one micro LED element 1.

For example, the first connection pad 81-1 and the second connection pad 81-2 may transmit the electrical signals transmitted from one thin film transistor to one micro LED element 1 to operate and control one micro LED element 1.

The adhesive layer 110 may be formed of a polymer material containing nano- or micro-unit conductive particles C. For example, the adhesive layer 110 may include an anisotropic conductive film (ACF) or an anisotropic conductive paste (ACP).

Here, the ACF may be an anisotropic conductive film that conducts electricity in only one direction in a state in which fine conductive particles C are mixed in an adhesive resin to form a film.

Further, the ACP may be an anisotropic conductive material that conducts electricity in only one direction in a state in which the fine conductive particles C are mixed in the adhesive resin to maintain an adhesive property.

In addition, the conductive particles C may be metal particles such as Ni and Cu, carbon, solder balls, or polymer balls coated with metal. Further, the conductive particles C may be aligned and disposed in a non-conductive material or disposed randomly therein.

Accordingly, the adhesive layer 110 may electrically connect the plurality of connection pads 81 to the plurality of electrode pads 40 through the conductive particles C.

For example, the conductive particles C may be disposed between the first electrode pad 40-1 and the first connection pad 81-1 to electrically connect the first electrode pad 40-1 to the first connection pad 81-1. Further, the conductive particles C may be disposed between the second electrode pad 40-2 and the second connection pad 81-2 to electrically connect the second electrode pad 40-2 to the second connection pad 81-2. The position between the electrode pads 40 and the connection pads 81 may be referred to as a first position.

In addition, the adhesive layer 110 may fill spaces formed around the plurality of connection pads 81 and the plurality of electrode pads 40. The position surrounding the connection pads 81 and the electrode pads 40 may be referred to as a second position. Accordingly, because the adhesive layer 110 is formed of the non-conductive material, it is possible to prevent electrical short from occurring by insulating between the plurality of connection pads 81 and between the plurality of electrode pads 40. In other words, the conductive particles C formed directly between the connection pads 81 and the electrode pads 40 may ensure electrical connection, while the non-conductive adhesive layer 110 surrounding the connection pads 81 and the electrode pads 40 may prevent the occurrence of electrical shorts.

Further, the adhesive layer 110 may be disposed to surround the side surfaces of the micro LED element 1. Accordingly, the adhesive layer 110 may electrically connect the micro LED element 1 to the substrate 80 and stably fix the micro LED element 1 on the substrate 80 at the same time.

That is, even if an impact is applied to one micro LED display module 1000 to which the micro LED element 1 is coupled, the adhesive layer 110 may prevent the micro LED element 1 from being separated from the substrate 80.

The micro LED element 1 is the same as the structure described above in FIGS. 1 and 2 and may be disposed on the substrate 80. Specifically, the plurality of electrode pads 40 of the micro LED element 1 may be disposed to face the plurality of connection pads 81 of the substrate 80.

For example, the first electrode pad 40-1 may be disposed to face the first connection pad 81-1, and the second electrode pad 40-2 may be disposed to face the second connection pad 81-2.

Further, the plurality of electrode pads 40 may be electrically connected to the plurality of connection pads 81 of the substrate 80 through the conductive particles C.

For example, the first electrode pad 40-1 may be electrically connected to the first connection pad 81-1 through the conductive particles C, and the second electrode pad 40-2 may be electrically connected to the second connection pad 81-2 through the conductive particles C.

At this time, by disposing the conductive filler 50 in the dents 41 formed on the plurality of electrode pads 40, an area that may physically be in contact with the conductive particles C may increase.

For example, the outer surface 50a of the conductive filler 50 forms a surface capable of contacting the conductive particles C, together with the contact surfaces 40a of the plurality of electrode pads 40, thereby making it possible to implement a stable electrical connection of the micro LED element 1.

Specifically, if the conductive filler 50 is not disposed in the dents 41, the conductive particles C may be disposed inside the dents 41 formed in the manufacturing process of the micro LED element 1. Accordingly, when considering a size of the fine conductive particles C, the plurality of electrode pads 40 may not be electrically connected to the plurality of connection pads 81 at the portions where the dents 41 are formed.

Therefore, the conductive filler 50 may fill the dents 41 formed on the contact surfaces 40a-1 and 40a-2 of the plurality of electrode pads 40, thereby implementing the stable electrical connection of the micro LED element 1.

In addition, when considering a process of connecting the conductive particles C to the plurality of electrode pads 40 and the plurality of connection pads 81 through thermal compression that is applied to a plurality of micro LED elements 1 transferred on the substrate 80, the compression may not be applied to the conductive particles C disposed inside the dents 41. Therefore, by additionally disposing the conductive filler 50, it is possible to prevent the presence of conductive particles C disposed inside the dents 41 to which compression is not applied.

In addition, considering that thousands and tens of thousands of micro LED elements 1 are disposed on the substrate 80, and the adhesive layer 110 is a cured structure, when the micro LED elements 1 are not electrically connected, a process of repairing the electrical connection problem may be time consuming and expensive.

Therefore, by providing a conductive filler 50 to prevent a defective electrical connection of some of the large number of micro LED elements 1, it is possible to significantly improve a manufacturing efficiency of the micro LED display module 1000.

In addition, a display module 1000 according to an example embodiment may be applied to a wearable device, a portable device, a handheld device, and an electronic product or an electronic device having various displays in a single unit, and may be applied to small display devices such as monitors for personal computers and televisions (TVs), and large display devices such as digital signage and electronic displays through a plurality of assembly arrangements.

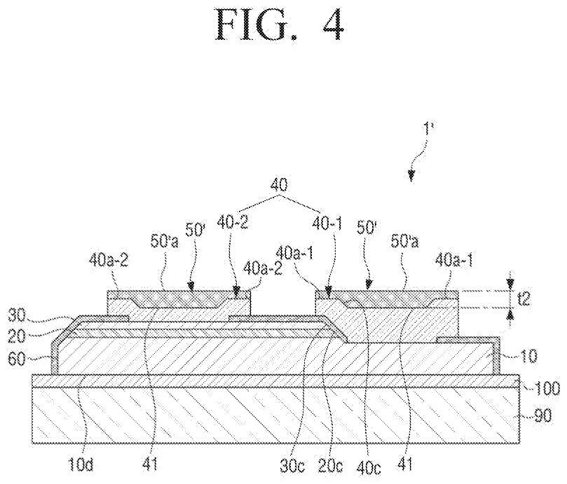

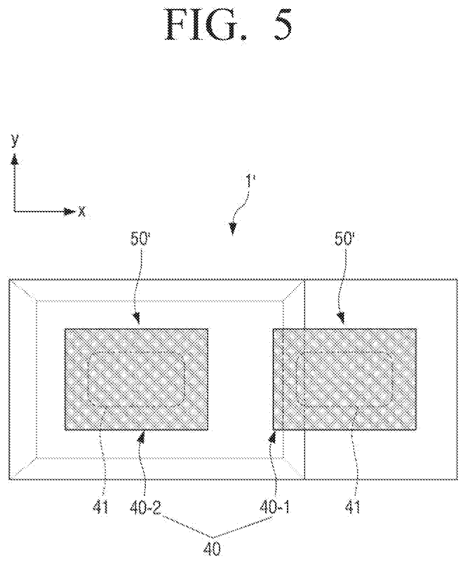

Hereinafter, a structure of a micro LED element 1′ according to an embodiment will be described with reference to FIGS. 4 and 5.

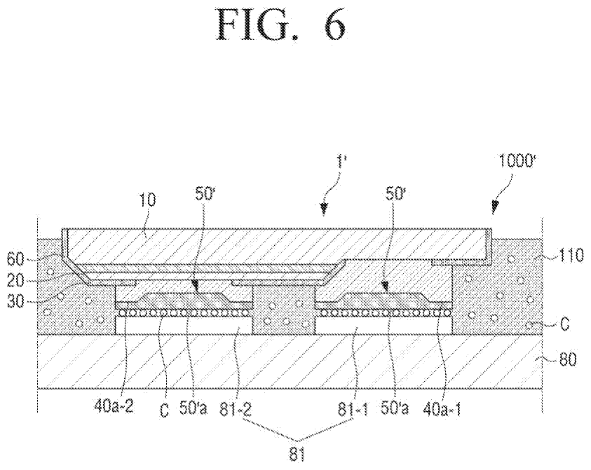

FIG. 4 is a cross-sectional view illustrating a micro LED element 1′ according to an embodiment, FIG. 5 is a top view illustrating the micro LED element 1′ according to an embodiment, and FIG. 6 is a cross-sectional view illustrating a portion of a micro LED display module 1000′ according to an embodiment.

Here, the same member number is used for the same configuration, and the duplicated description is omitted. For example, the first semiconductor layer 10, the active layer 20, the second semiconductor layer 30, the plurality of electrode pads 40, the insulating member 60, the substrate 80, the growth substrate 90, the buffer layer 100, and the adhesive layer 110 are the same as described above, and the duplicated description is thus omitted.

A conductive filler 50′ may be disposed on the contact surfaces 40a-1 and 40a-2 of the first electrode pad 40-1 and the second electrode pad 40-2. For example, the conductive filler 50′ may be formed of a second thickness t2 that is thicker than the first thickness of the conductive filler 50 illustrated in FIG. 1.

The conductive filler 50′ may fill the dents 41 of the plurality of electrode pads 40 and may also be disposed on the upper portions of the contact surfaces 40a-1 and 40a-2. Accordingly, as illustrated in FIG. 6, the plurality of electrode pads 40 do not directly contact the conductive particles C, but the conductive filler 50′ may directly contact the conductive particles C.

That is, an outer surface 50a′ (i.e., an upper surface as shown in FIG. 4) of the conductive filler 50′ may be in direct contact with the conductive particles C, thereby electrically connecting the micro LED element 1′ and the substrate 80.

Accordingly, the plurality of electrode pads 40 may be electrically connected to the plurality of connection pads 81 through the conductive filler 50′ and the conductive particles C.

Further, the conductive filler 50′ covers the contact surfaces 40a-1 and 40a-2 of the plurality of electrode pads 40, and therefore, even if there are additional flaws and cavities on the plurality of electrode pads 40, the conductive filler 50′ covers the additional flaws and cavities, thereby implementing the stable electrical connection of the micro LED element 1.

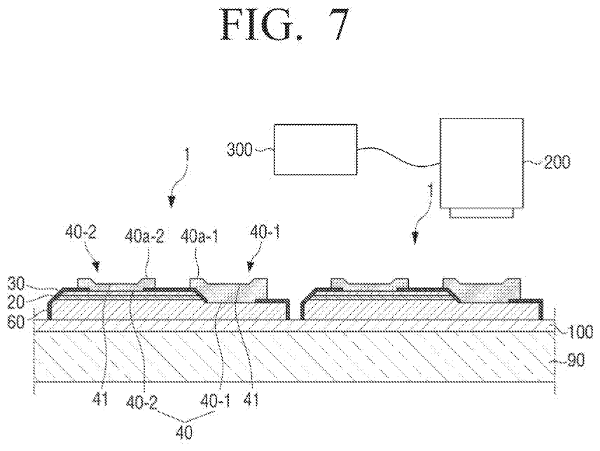

Hereinafter, a method of manufacturing the micro LED element 1 according to an embodiment will be described with reference to FIGS. 7 to 11B.

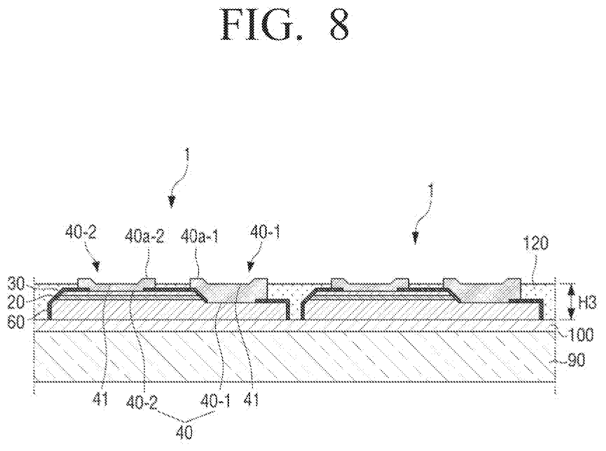

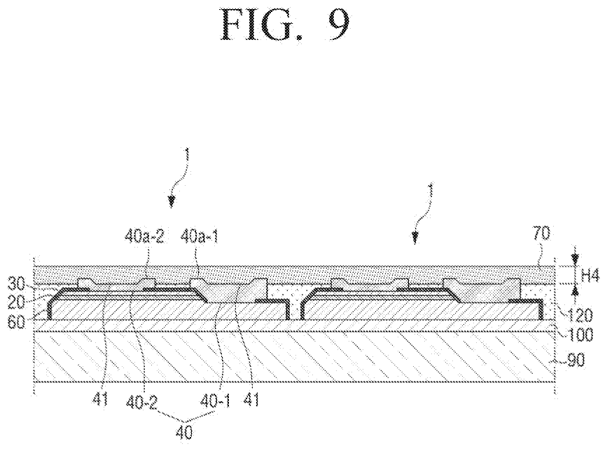

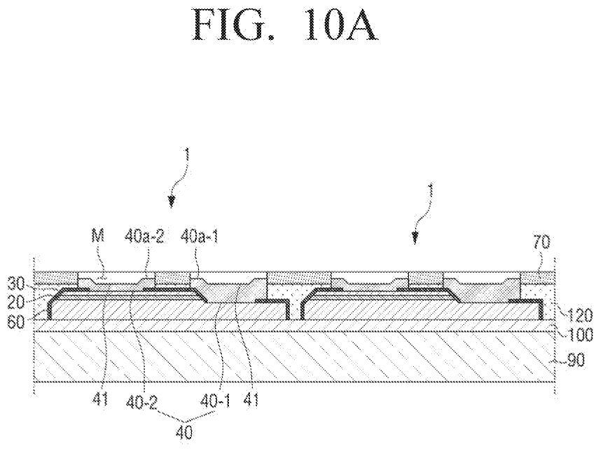

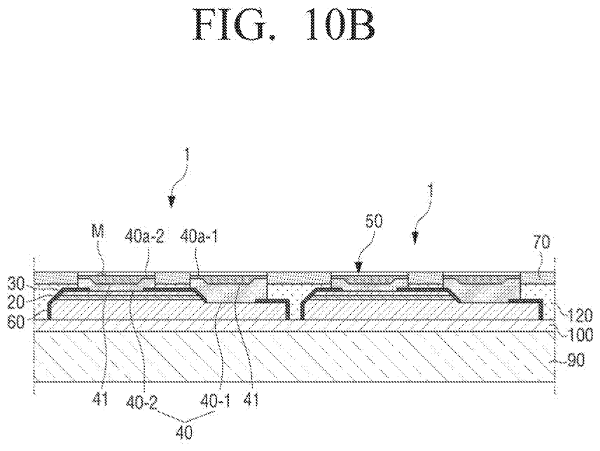

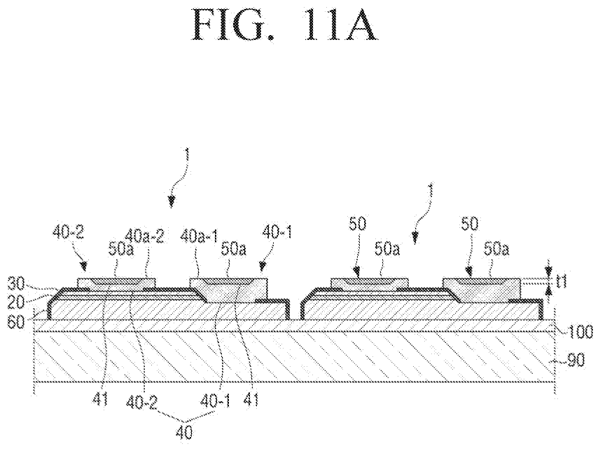

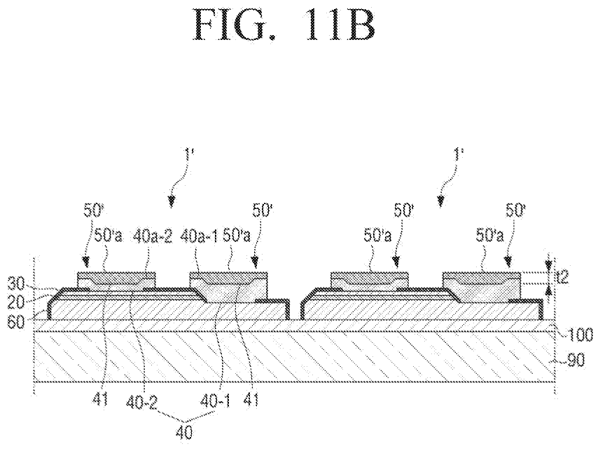

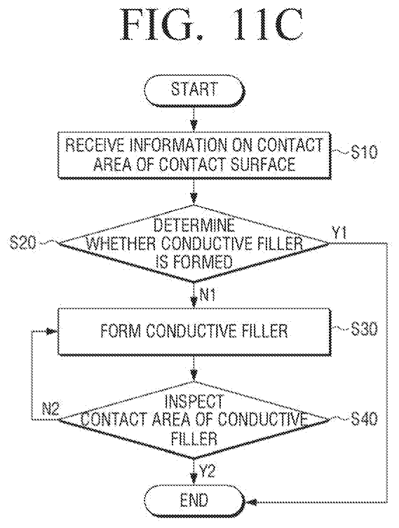

FIG. 7 is a cross-sectional view illustrating a micro LED element 1 in which a conductive filler 50 is not formed, FIG. 8 is a cross-sectional view illustrating that a base layer 120 is formed in a structure of FIG. 7, FIG. 9 is a cross-sectional view illustrating that a photoresist layer 70 is formed in a structure of FIG. 8, FIG. 10A is a cross-sectional view illustrating that plating holes M are formed on a plurality of electrode pads 40-1 and 40-2 according to an embodiment, FIG. 10B is a cross-sectional view illustrating that a conductive filler 50 is formed through a plating process in the plating holes M formed according to an embodiment, FIG. 11A is a cross-sectional view illustrating that a conductive filler 50 is formed according to an embodiment, FIG. 11B is a cross-sectional view illustrating that a conductive filler 50′ is formed according to another embodiment, and FIG. 11C is a flowchart illustrating a method of manufacturing a micro LED element 1 according to an embodiment.

As illustrated in FIG. 7, a plurality of manufactured micro LED elements 1 may be disposed on the growth substrate 90 and the buffer layer 100. Here, the plurality of micro LED elements 1 are in a state in which the conductive filler 50 is not formed.

Thereafter, a processor 300 may receive information on a contact area of at least one contact surface 40a-1 and 40a-2 of the first electrode pad 40-1 and the second electrode pad 40-2 of the micro LED element 1 through an inspection device 200 (S10 of FIG. 11C).

Here, the processor 300 may be connected to the inspection device 200 to transmit and receive various information, and may perform the overall manufacturing process and inspection process of forming the conductive filler 50 on the micro LED element 1.

Further, the processor 300 may include one or more of a central processing unit (CPU), a controller, an application processor (AP), a communication processor (CP), or an ARM processor.

In addition, the inspection device 200 is a device for inspecting the contact surfaces of the plurality of electrode pads 40-1 and 40-2 of the micro LED element 1, and may be various devices such as a vision inspection device including a camera, and an automatic optical inspection (AOI) device

Next, the processor 300 may determine whether the conductive filler 50 is formed on the micro LED element 1 based on a checked contact area (S20 of FIG. 11C). For example, the processor 300 may perform the determination based on whether the checked contact area exceeds a predetermined area value (i.e., a predetermined value).

Specifically, if the checked contact area of the plurality of electrode pads 40-1 and 40-2 does not reach a predetermined area value for electrical connection (N1 of FIG. 11C), the processor 300 may determine to perform a process of forming the conductive filler 50 for the micro LED element 1 (S30 of FIG. 11C).

On the other hand, if the checked contact area of the plurality of electrode pads 40-1 and 40-2 exceeds the predetermined area value for electrical connection (Y1 of FIG. 11C), the processor 300 may determine not to form the conductive filler 50 for the micro LED element 1.

Here, the exceeding of the predetermined area value may include a case where the dent 41 is not formed in the micro LED element 1.

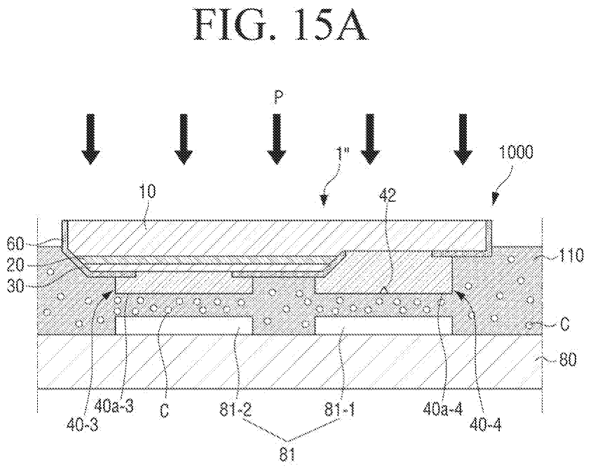

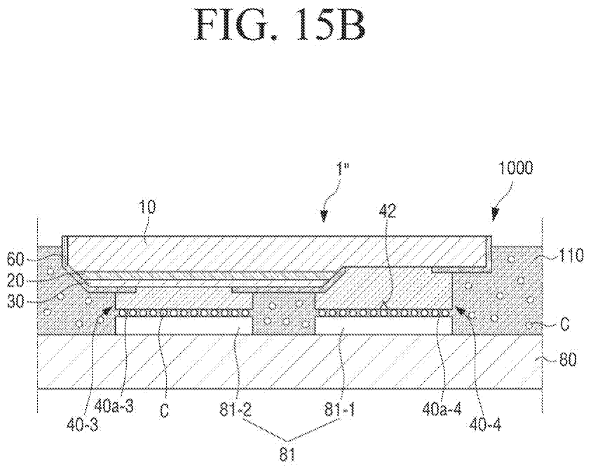

For example, as illustrated in FIG. 15A, the exceeding of the predetermined area may include a case where the dent is not formed in a third electrode pad 40-3 and the contact area exceeds the predetermined area. In addition, the exceeding of the predetermined area may include a case where the dent 42 is formed as in a fourth electrode pad 40-4, but a size of the dent 42 is fine and the contact area exceeds the predetermined contact area even though the dent 42 is present.

Therefore, by selectively forming the conductive filler 50 without collectively forming the conductive filler 50 with respect to the micro LED element 1, an efficient process may be performed.

Next, as illustrated in FIG. 8, a base layer 120 may be coated around the plurality of manufactured micro LED elements 1 and on a buffer layer 100.

Specifically, the base layer 120 is stacked to surround the side surfaces of the plurality of electrode pads 40, but is not stacked on the contact surfaces 40a-1, 40a-2 and the dents 41 of the plurality of electrode pads 40.

For example, the base layer 120 may be formed at a third height H3 such that an upper surface of the base layer 120 as shown in FIG. 8 is lower than the contact surfaces 40a-1, 40a-2 of the plurality of electrode pads 40.

The base layer 120 may be formed of a conductive material.

Next, as illustrated in FIG. 9, a photoresist layer 70 may be formed on the base layer 120. Here, the photoresist layer 70 may be formed of a resin that causes a chemical change when irradiated with light. For example, the photoresist layer 70 may be formed of methyl polymethacrylate, naphthoqinone diazide, polybutene-l-sulfone, or the like.

The photoresist layer 70 may be stacked on the contact surfaces 40a-1 and 40a-2 of the plurality of electrode pads 40 and the dents 41 that are not coated with the base layer 120. That is, the photoresist layer 70 may be disposed on the contact surfaces 40a-1 and 40a-2 and the dents 41 of the plurality of electrode pads 40.

Further, the photoresist layer 70 may be formed at a fourth height H4. Here, the fourth height H4 may mean a height capable of completely covering the plurality of electrode pads 40 exposed to the outside.

Next, as illustrated in FIG. 10A, plating holes M may be formed through exposure and developing processes at positions corresponding to the plurality of electrode pads 40-1 and 40-2. Here, the plating holes M may be formed on the plurality of electrode pads 40-1 and 40-2 in the photoresist layer 70. Accordingly, the dents 41 and the contact surfaces 40a-1 and 40a-2 of the plurality of electrode pads 40-1 and 40-2 may be exposed.

Thereafter, as illustrated in FIG. 10B, the conductive filler 50 may be formed on the exposed dents 41 and contact surfaces 40a-1 and 40a-2 of the plurality of electrode pads 40-1 and 40-2 through a plating process.

Next, as illustrated in FIGS. 11A and 11B, the base layer 120 and the photoresist layer 70 may be removed, and the conductive filler 50 may be cut to a desired height through a chemical mechanical polishing (CMP) process at the same time.

For example, as illustrated in FIG. 11A, the photoresist layer 70 may be planarized to have a first thickness t1. Accordingly, the conductive filler 50 disposed in the dents 41 is formed, and the contact surfaces 40a-1 and 40a-2 of the plurality of electrode pads 40 may be exposed at the same time so that an upper surface of the conductive filler 50 as shown in FIG. 11A is coplanar with the contact surfaces 40a-1 and 40a-2 of the plurality of electrode pads 40.

Further, through the CMP process, the outer surface 50a of the conductive filler 50 and the contact surfaces 40a-1 and 40a-2 may be formed to be substantially parallel and coplanar. Accordingly, when the manufactured micro LED elements 1 are disposed on the substrate 80, a parallel position of the micro LED element 1 may be implemented, and a stable contact of the conductive particles C may also be implemented.

Accordingly, a plurality of micro LED elements 1 in which the conductive filler 50 is filled in the dents 41 of the plurality of electrode pads 40 may be manufactured on the growth substrate 90.

Through the series of processes, it is possible to form the conductive filler 50 for a large number of micro LED elements 1 manufactured on the growth substrate 90. Therefore, a manufacturing efficiency of the plurality of micro LED elements 1 having the conductive filler 50 may be greatly improved.

As illustrated in FIG. 11B, the CMP process may be performed on a conductive filler 50′ until the conductive filler 50′ has a second thickness t2. Here, the second thickness t2 may be greater than the first thickness t1.

Accordingly, the conductive filler 50 may be disposed to completely cover the contact surfaces 40a-1 and 40a-2 of the plurality of electrode pads 40.

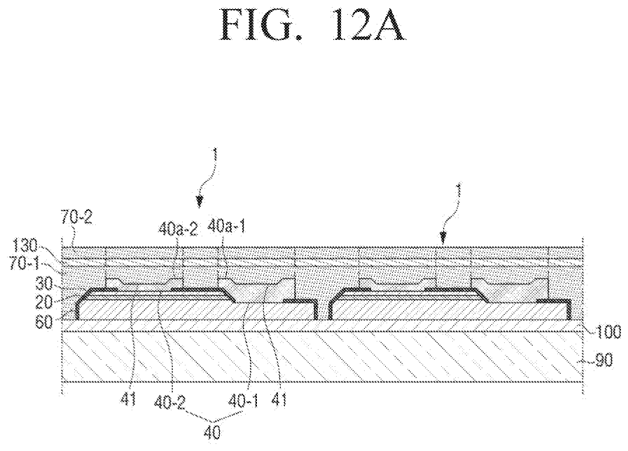

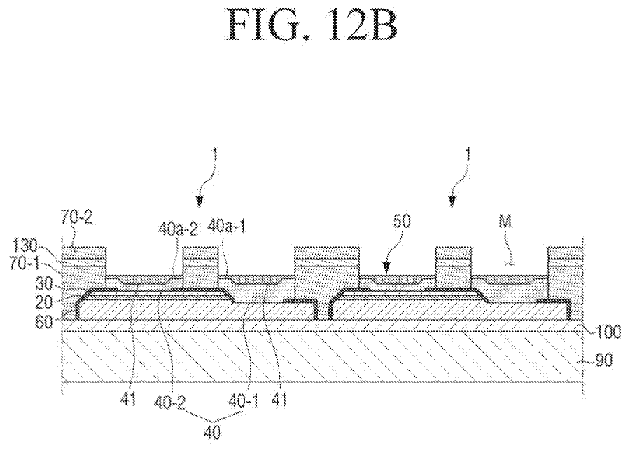

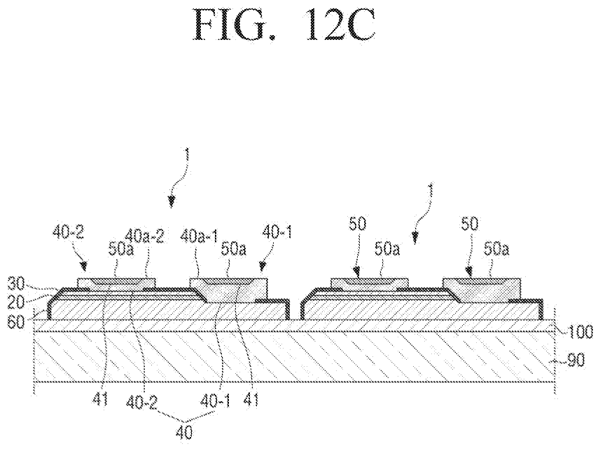

Hereinafter, a process of forming the conductive filler 50 according to an embodiment will be described with reference to FIGS. 12A to 12C.

FIG. 12A is a cross-sectional view illustrating a process of forming a conductive filler 50 according to an embodiment, FIG. 12B is a cross-sectional view illustrating that the conductive filler 50 is formed in plating holes M formed in a structure of FIG. 12A, and FIG. 12C is a cross-sectional view illustrating that the conductive filler 50 is formed according to the process according to an embodiment.

First, as illustrated in FIG. 12A, a first photoresist layer 70-1 covering the plurality of electrode pads 40-1 and 40-2 of the micro LED element 1, a seed layer 130 stacked on the first photoresist layer 70-1, and a second photoresist layer 70-2 stacked on the seed layer 130 may be sequentially stacked.

Here, the first photoresist layer 70-1 and the second photoresist layer 70-2 may be formed of a resin that causes a chemical change when irradiated with light. For example, the photoresist layers 70-1 and 70-2 may be formed of methyl polymethacrylate, naphthoqinone diazide, polybutene-1-sulfone, or the like.

Further, the seed layer 130 may be formed of a conductive material. For example, the seed layer 130 may be formed of copper (Cu).

Next, plating holes M may be formed through exposure and developing processes at positions corresponding to the plurality of electrode pads 40-1 and 40-2. Accordingly, the dents 41 and the contact surfaces 40a-1 and 40a-2 of the plurality of electrode pads 40-1 and 40-2 may be exposed. In addition, the conductive filler 50 may be formed on the exposed dents 41 and contact surfaces 40a-1 and 40a-2 of the plurality of electrode pads 40-1 and 40-2 through a plating process as shown in FIG. 12B.

Thereafter, as illustrated in FIG. 12C, the first photoresist layer 70-1, the seed layer 130, and the second photoresist layer 70-2 may be removed, and the outer surface 50a of the conductive filler 50 and the contact surfaces 40a-1 and 40a-2 may be formed to be parallel and coplanar through the CMP process. Accordingly, when the manufactured micro LED elements 1 are disposed on the substrate 80, a parallel position of the micro LED element 1 may be implemented, and a stable contact of the conductive particles C may also be implemented.

Further, as illustrated in FIG. 11C, after the conductive filler 50 is formed (S30), the processor 300 may additionally inspect a contact area of the conductive filler 50 (S40). Accordingly, if the contact area of the conductive filler 50 does not reach a predetermined value for electrical contact with the substrate 80 (N2), the processor 300 may perform an additional plating process on the conductive filler 50.

That is, the processor 300 may improve manufacturing reliability by implementing a contact area of the micro LED element 1 of a predetermined value or more through a feedback process.

Further, if the contact area of the conductive filler 50 reaches the predetermined value for electrical contact with the substrate 80 (Y2), the processor 300 may complete the inspection and manufacturing process for the micro LED element 1.

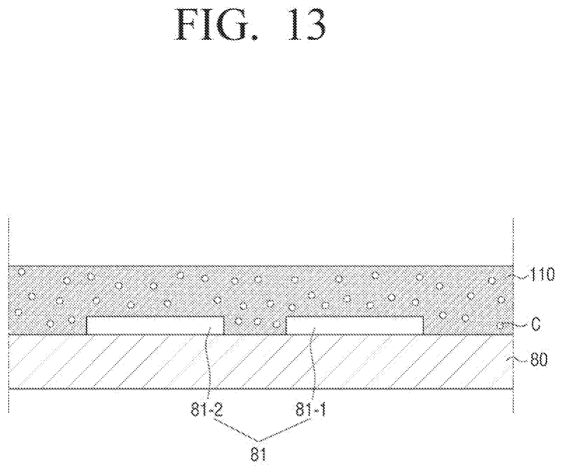

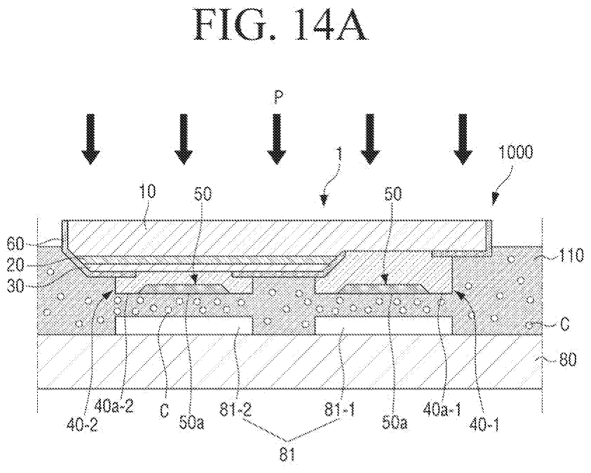

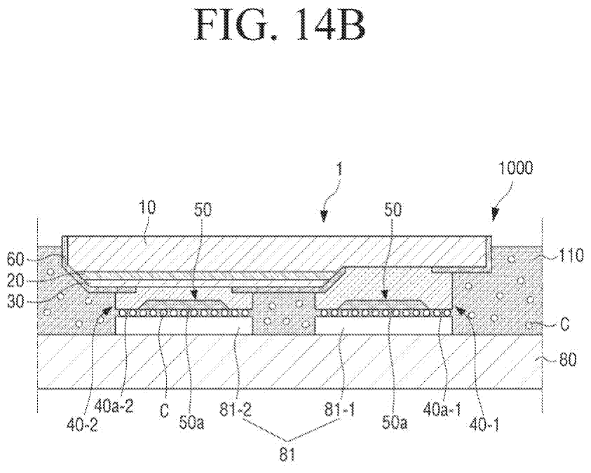

Hereinafter, a process of bonding the micro LED element 1 to the substrate 80 according to an embodiment will be described with reference to FIGS. 13 to 14B.

FIG. 13 is a cross-sectional view illustrating that an adhesive layer 110 is coated on a substrate 80 according to an embodiment, FIG. 14A is a cross-sectional view illustrating that the micro LED element 1 according to an embodiment is transferred in a structure of FIG. 13, and FIG. 14B is a cross-sectional view illustrating that a micro LED element 1 according to an embodiment is coupled to the substrate 80.

Here, the same member number is used for the same configuration, and the duplicated description is omitted. For example, the substrate 80, the adhesive layer 110, and the micro LED element 1 are the same as the above-described configurations, and the duplicated description will be thus omitted.

As illustrated in FIG. 13, an adhesive layer 110 including conductive particles C may be coated on the substrate 80 on which a plurality of connection pads 81 are formed. Next, as illustrated in FIG. 14A, the micro LED element 1 may be transferred onto the substrate 80 on which the adhesive layer 110 is coated.

Here, each of the plurality of electrode pads 40 of the micro LED element 1 may be disposed to face a respective connection pad of the plurality of connection pads 81 of the substrate 80. For example, the first electrode pad 40-1 may be disposed to face the first connection pad 81-1, and the second electrode pad 40-2 may be disposed to face the second connection pad 81-2.

Further, the structure of FIG. 14A is in a state in which the micro LED element 1 is not electrically connected to the substrate 80.

Next, thermal compression P may be applied to the transferred micro LED element 1. Here, the thermal compression P may mean the application of temperature and pressure to cure the adhesive layer 110.

Thereafter, as illustrated in FIG. 14B, the micro LED element 1 may be electrically connected to the substrate 80 through conductive particles C that are positioned between the electrode pads 40 and the connection pads 81 through the thermal compression P.

Further, the adhesive layer 110 may cover a portion of the side surfaces of the micro LED element 1. Accordingly, the adhesive layer 110 may fix the micro LED element 1 and reflect the sidelight emitted by the micro LED element 1, thereby improving the light efficiency of the micro LED element 1.

Hereinafter, a process of bonding a micro LED element 1″ to the substrate 80 according to an embodiment will be described with reference to FIGS. 15A and 15B.

FIG. 15A is a cross-sectional view illustrating that a micro LED element 1″ according to an embodiment is transferred in a structure of FIG. 13 and FIG. 15B is a cross-sectional view illustrating that the micro LED element 1″ according to an embodiment is coupled to a substrate.

Here, the same member number is used for the same configuration, and the duplicated description is omitted. For example, the substrate 80 and the adhesive layer 110 are the same as the above-described configurations, and the duplicated description will be thus omitted.

A micro LED element 1″ according to an embodiment has a difference that the structure of a plurality of electrode pads 40-3 and 40-4 is different from that of the plurality of electrode pads 40-1 and 40-2 of the micro LED element 1′ according to an embodiment, and other structures may be the same.

For example, the configurations of the micro LED element 1″ other than a third electrode pad 40-3 and a fourth electrode pad 40-4 may be the same as those of the above-described micro LED element 1.

According to a manufacturing process of the micro LED element 1″, the dent 41 may not be formed on the third electrode pad 40-3 of the micro LED element 1″. Accordingly, an area of a contact surface 40a-3 of the third electrode pad 40-3 may be greater than a predetermined contact area.

In addition, the fourth electrode pad 40-4 may include a dent 42, but an area of a contact surface 40a-4 of the fourth electrode pad 40-4 excluding the dent 42 may be greater than the predetermined contact area.

Therefore, the conductive filler 50 is unnecessary and may not be formed on the third electrode pad 40-3 and the fourth electrode pad 40-4. However, the micro LED element 1″ was described as including only the third electrode pad 40-3 and the fourth electrode pad 40-4, but if necessary, the micro LED element 1″ may include the first electrode pad 40-1 and the third electrode pad 40-3, or the first electrode pad 40-1 and the fourth electrode pad 40-4.

Next, as illustrated in FIG. 15A, thermal compression P may be applied to the micro LED element 1″ transferred onto the substrate 80 on which the adhesive layer 110 is coated.

Thereafter, as illustrated in FIG. 15B, the micro LED element 1″ may be electrically connected to the substrate 80 through conductive particles C through the thermal compression P.

On the other hand, the methods according to the embodiments described above may be implemented in the form of an application installable on an existing electronic apparatus.

In addition, the methods according to the embodiments described above may be implemented by only upgrading software or hardware of the existing electronic apparatus.

In addition, the embodiments described above may also be performed through an embedded server included in the electronic apparatus, or an external server of the electronic apparatus.

The embodiments described above may be implemented in a computer or similar device readable recording medium using software, hardware, or a combination thereof. In some cases, the embodiments described in the specification may be implemented by the processor 300 itself. According to software implementation, the embodiments such as procedures and functions described in the disclosure may be implemented as separate software modules. Each of the software modules may perform one or more functions and operations described in the disclosure.

Computer instructions for performing processing operations according to the embodiments described above may be stored in a non-transitory computer-readable medium. The computer instructions stored in the non-transitory computer-readable medium allow a specific device to perform the processing operations according to the embodiments described above when they are executed by a processor of the specific device.

The non-transitory computer-readable medium refers to a medium that stores data semi-permanently and is read by a device, not a medium storing data for a short time such as a register, a cache, a memory, and the like. A specific example of the non-transitory computer-readable medium may include a compact disk (CD), a digital versatile disk (DVD), a hard disk, a Blu-ray disk, a universal serial bus (USB), a memory card, a read only memory (ROM), or the like.

In addition, each operation included in the computer-readable recording medium may be implemented in the form of code. Further, the operation implemented with each code may be executed by the manufacturing apparatus of the micro LED element and the micro LED display module.

Although the embodiments have been individually described hereinabove, the respective embodiments are not necessarily implemented singly, but may also be implemented so that configurations and operations thereof are combined with those of one or more other embodiments.

Although the embodiments have been illustrated and described hereinabove, the disclosure is not limited to the specific embodiments described above, but may be variously modified by those skilled in the art to which the disclosure pertains without departing from the scope and spirit of the disclosure claimed in the accompanying claims. Such modifications should be understood from the technical spirit or the prospect of the disclosure.

What is claimed is:

1. A light emitting diode (LED) element comprising:
an active layer configured to generate light;
a first semiconductor layer disposed on a first surface of the active layer and doped with an n-type dopant;
a second semiconductor layer disposed on a second surface of the active layer opposite to the first surface, the second semiconductor layer being doped with a p-type dopant;
a first electrode pad and a second electrode pad electrically connected to the first semiconductor layer and the second semiconductor layer, respectively, the first electrode pad comprising a first contact surface and the second electrode pad comprising a second contact surface; and
a conductive filler disposed on at least one contact surface from among the first contact surface and the second contact surface to increase a contact area of the at least one contact surface.

2. The LED element as claimed in claim 1, wherein a portion of the at least one contact surface is exposed through the conductive filler.

3. The LED element as claimed in claim 1, wherein a surface of the conductive filler is substantially coplanar with a portion of the at least one contact surface.

4. The LED element as claimed in claim 1, wherein the conductive filler covers an entirety of the at least one contact surface.

5. The LED element as claimed in claim 1, wherein the first semiconductor layer comprises a light exposure surface through which the light generated in the active layer is transmitted, and
wherein the first electrode pad and the second electrode pad are disposed on an opposite side of the first semiconductor layer with respect to the light exposure surface.

6. The LED element as claimed in claim 1, wherein at least one contact surface from among the first contact surface and the second contact surface has a dent formed therein, and
wherein the conductive filler disposed on the at least one contact surface to fill the dent.

7. A light emitting diode (LED) display module comprising:
a substrate;
a first connection pad and a second connection pad disposed on a surface of substrate;
an LED element disposed on the substrate; and
an adhesive layer disposed on the substrate to electrically connect the LED element to the substrate,
wherein the LED element comprises:
a first electrode pad and a second electrode pad disposed to face the first connection pad and the second connection pad, respectively, the first electrode pad comprising a first contact surface and the second electrode pad comprising a second contact surface; and
a conductive filler configured to increase a contact area of at least one contact surface from among the first contact surface of the first electrode pad and the second contact surface of the second electrode pad.

8. The LED display module as claimed in claim 7, wherein a portion of the at least one contact surface is exposed through the conductive filler.

9. The LED display module as claimed in claim 7, wherein the conductive filler covers an entirety of the at least one contact surface.

10. The LED display module as claimed in claim 7, wherein the adhesive layer comprises a plurality of conductive particles, and
wherein the plurality of conductive particles are disposed between the first electrode pad and the first connection pad to electrically connect the first electrode pad to the first connection pad, and are disposed between the second electrode pad and the second connection pad to electrically connect the second electrode pad to the second connection pad.

11. The LED display module as claimed in claim 7, wherein the adhesive layer comprises an anisotropic conductive film (ACF) or an anisotropic conductive paste (ACP).

12. A method of manufacturing a light emitting diode (LED) element, the method comprising:
checking a contact area of at least one contact surface from a first contact surface of a first electrode pad and a second contact surface of a second electrode pad of the LED element;
determining whether a conductive filler of the LED element is formed, based on the checked contact area; and
forming the conductive filler on the at least one contact surface based on a result of the determining whether the conductive filler is formed.

13. The method as claimed in claim 12, wherein the determining whether the conductive filler is formed is performed based on whether the checked contact area exceeds a predetermined area value.

14. The method as claimed in claim 12, further comprising, after the forming the conductive filler, inspecting a contact area of the conductive filler.

15. The method as claimed in claim 12, wherein the forming the conductive filler comprises:
coating a base layer on the LED element to expose the at least one contact surface;
coating a photoresist layer on the base layer;
forming a plating hole on the at least one contact surface;
depositing the conductive filler in the plating hole; and
removing the base layer and the photoresist layer.

16. The method as claimed in claim 12, wherein the forming of the conductive filler comprises:
coating a first photoresist layer to cover the LED element;
coating a seed layer on the first photoresist layer;
coating a second photoresist layer on the seed layer;
forming a plating hole on the at least one contact surface;
depositing the conductive filler in the plating hole; and
removing the first photoresist layer, the seed layer, and the second photoresist layer.
